(19) United States
(12) Patent Application Publication
(10) Pub. No.: US 2025/0313948 A1
(43) Pub. Date: Oct. 9, 2025

(54) HIGH-DENSITY PLASMA (HDP) TOPOGRAPHY IMPROVEMENT WITH PARTIAL GAPFILL CARBON

(71) Applicant: Applied Materials, Inc., Santa Clara, CA (US)

(72) Inventors: Abdul Aziz KHAJA, San Jose, CA (US); Li-Qun XIA, Cupertino, CA (US); Jingmei LIANG, San Jose, CA (US); Sanjay G. KAMATH, Fremont, CA (US); Ming-Jer LEE, Mission Viejo, CA (US)

(21) Appl. No.: 19/092,673

(22) Filed: Mar. 27, 2025

Related U.S. Application Data
(60) Provisional application No. 63/575,591, filed on Apr. 5, 2024.

(51) Int. Cl. C23C 16/04; H01L 21/306; H01L 21/3065; H01L 21/311

(52) U.S. Cl. CPC C23C 16/045; H01L 21/30625; H01L 21/3065; H01L 21/31111; H01L 21/31116

(57) ABSTRACT

Embodiments disclosed herein generally relate to high-density plasma (HDP) deposition and other gapfilling processes for semiconductor manufacturing. The process includes depositing a carbon gapfill layer into one or more trenches formed in an oxide layer of a semiconductor device structure, etching at least a portion of the oxide layer, etching, via a plasma-based etch process, the carbon gapfill layer, and performing a chemical mechanical polishing (CMP) process to planarize the oxide layer. Implementing such processes for HDP deposition and gapfilling results in various improvements in the manufacturing of semiconductor substrates.

### CROSS-REFERENCE TO RELATED APPLICATIONS

This application claims benefit of U.S. provisional patent application Ser. No. 63/575,591, filed Apr. 5, 2024, which is herein incorporated by reference in its entirety.

### BACKGROUND

### Field

Embodiments of the present disclosure generally relate to processes for semiconductor device manufacturing, and, more specifically, relate to gapfilling and high-density plasma chemical vapor deposition (HDPCVD) processes for semiconductor manufacturing.

### Description of the Related Art

Integrated circuits are made possible by processes which produce intricately patterned material layers on substrate surfaces. Producing patterned materials on a substrate requires controlled methods of formation and removal of exposed materials.

As device sizes continue to shrink, material formation may affect subsequent operations of semiconductor device fabrication. For example, in certain gapfilling operations, a material may be deposited via high-density plasma chemical vapor deposition (HDPCVD), often referred to simply as high-density plasma (HDP) deposition, to fill a trench or other gap formed between structures on a semiconductor substrate. Traditional HDP gapfill deposition processes typically result in excess material being unintentionally deposited onto structures themselves, in addition to the gaps or trenches therebetween. This excess material deposited onto the structures may be referred to as “overburden.” The overburden may create a highly non-uniform overall device topography, which can negatively impact device performance and subsequent processing operations.

Thus, there is a need for improved systems and methods for HDP and other gapfilling processes that can be used to produce high quality devices and structures.

### SUMMARY

Embodiments of the present disclosure generally relate to high-density plasma (HDP) deposition and other gapfilling processes for semiconductor manufacturing.

One exemplary method for processing includes depositing a carbon gapfill layer into one or more trenches formed in an oxide layer of a semiconductor device structure, etching at least a portion of the oxide layer, etching, via a plasma-based etch process, the carbon gapfill layer, and performing a chemical mechanical polishing (CMP) process to planarize the oxide layer.

Another exemplary method for processing includes depositing a carbon gapfill layer into one or more trenches formed in an oxide layer of a semiconductor device structure, the oxide layer formed by high-density plasma chemical vapor deposition (HDPCVD), etching at least a portion of the oxide layer, etching, via a plasma-based etch process, the carbon gapfill layer, depositing a silicon layer over the oxide layer using tetraethyl orthosilicate (TEOS), and performing a CMP process to planarize the silicon layer.

Another exemplary method for processing includes depositing, via a HDP deposition process, an oxide layer over one or more device structures, depositing a carbon gapfill layer into one or more trenches formed in the oxide layer, etching at least a portion of the oxide layer, etching, via a plasma-based etch process, the carbon gapfill layer, depositing a silicon layer over the oxide layer using TEOS, and performing a CMP process to planarize the silicon layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 shows a schematic illustration of an apparatus that can be used to conduct processing methods, according to embodiments.

FIG. 2 is a flow diagram of a method of processing a substrate of FIG. 1, according to embodiments.

FIGS. 3A-3G show schematic cross-sectional views of the substrate of FIG. 1 at various stages of the method of FIG. 2, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

High-density plasma (HDP) deposition processes are utilized in a wide range of applications for forming semiconductor device features. However, as overall dimensions of semiconductor devices continue to shrink, material layers need to be reduced in thickness and size to scale the features of such devices. And, as the device features are reduced in size, the aspect ratios of the features increase.

Conventional HDP deposition processes, and particularly, HDP gapfill deposition processes, can result in a thick overburden, or an excess of unintentionally deposited materials on device structures. Generally, overburden thickness depends on a width of an underlying structure—the wider the structure, the thicker the subsequent overburden. Thick overburden can create a highly non-uniform overall device topography, which can negatively impact device performance and subsequent processing operations.

Embodiments disclosed herein generally relate to processing methods for use in semiconductor device manufacturing. More particularly, embodiments described herein relate to a method for improved device topography after HDP deposition. Improving uniformity of overall device topography positively impacts device performance and subsequent processing operations.

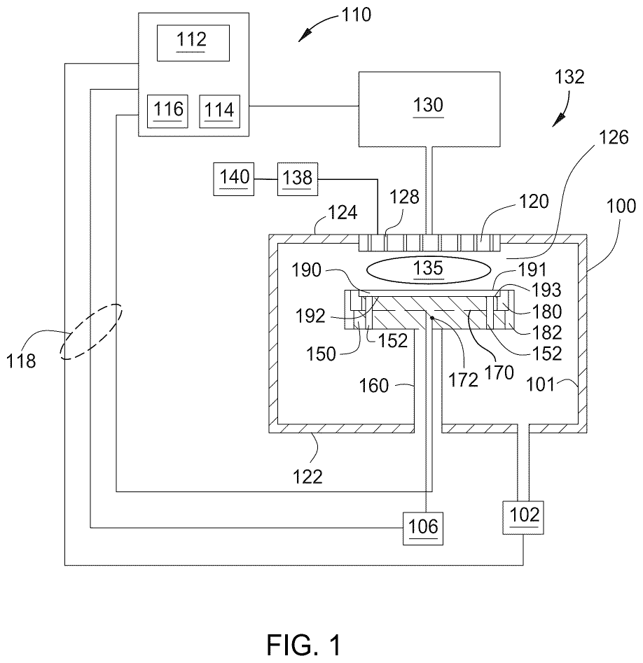

FIG. 1 shows a schematic illustration of a substrate processing system 132 that can be used to conduct processing methods in accordance with embodiments described herein. Examples of suitable systems, which can be used as the substrate processing system 132, include the CENTURA® systems which may use a DxZ™ processing chamber, PRECISION™ 5000 systems, PRODUCER® SE or GT processing chamber or system, which are commercially available from Applied Materials, Inc., Santa Clara, Calif. It is contemplated that other processing systems, including those available from other manufacturers, may be adapted to practice the embodiments described herein.

The substrate processing system 132 includes a processing chamber 100 coupled to a gas panel 130 and a controller 110.

The processing chamber 100 may be a plasma-enhanced chemical vapor deposition (PECVD) chamber as shown, or other suitable plasma processing chamber. Examples of a processing chamber 100 that may be adapted to benefit from the disclosure include PECVD chambers, such as but not limited to the CENTURA® apparatus, the PRODUCER® apparatus, the PRODUCER® GT apparatus, the PRODUCER® XP Precision™ apparatus, the PRODUCER® SE™ apparatus, and the TESSERACT® apparatus, which are available from Applied Materials, Inc., Santa Clara, Calif. It is contemplated that processing chambers from other manufacturers may also be adapted to benefit from the embodiments described herein.

Although FIG. 1 described herein is illustrative of a PECVD chamber, the processing chamber 100 should not be construed or interpreted as limiting the scope of the embodiments described herein. The embodiments described herein can be equally applied to an apparatus utilized for chemical vapor deposition (CVD) (e.g., high-density plasma CVD (HDPCVD)), physical vapor deposition (PVD), implanting, annealing, and plasma-treating materials on semiconductor substrates, among others.

The processing chamber 100 generally includes a top 124, a side 101, and a bottom wall 122 that define an interior processing volume 126. A substrate support 150 is provided in the interior processing volume 126 of the processing chamber 100. The substrate support 150 is supported by a stem 160 and can be fabricated from aluminum, ceramic, and other suitable materials. The substrate support 150 can be moved in a vertical direction inside the processing chamber 100 using a displacement mechanism (not shown).

The substrate support 150 includes a first edge ring 180 disposed about the substrate support 150, and a second edge ring 182 disposed about the substrate support 150 and the first edge ring 180. The edge rings 180, 182 protect the substrate support 150 and/or a substrate 190 disposed on a support surface 192 of the substrate support 150. In some aspects, the edge rings 180, 182 are made of alumina (Al₂O₃) or other suitable material. In certain embodiments, one or more additional processing rings, can also be disposed about the substrate support 150 and arranged along with the first edge ring 180 and/or second edge ring 182 to protect the substrate support 150 and/or substrate 190.

The substrate support 150 further includes an embedded heater element 170 suitable for controlling the temperature of the substrate 190. The substrate support 150 may be resistively heated by applying an electric current from a power supply 106 to the heater element 170. The heater element 170 may be made of a nickel-chromium wire encapsulated in a nickel-iron-chromium alloy (e.g., INCOLOY® alloy) sheath tube. The electric current supplied from the power supply 106 is regulated by the controller 110 to control the heat generated by the heater element 170, thereby maintaining the substrate 190 and the substrate support 150 at a substantially constant temperature during film deposition. The supplied electric current may be adjusted to selectively control the temperature of the substrate support 150 in a range from about 100 degrees Celsius (° C.) to about 700° C.

A temperature sensor 172, such as a thermocouple, may be embedded in the substrate support 150 to monitor the temperature of the substrate support 150 in a conventional manner. The measured temperature is used by the controller 110 to control the power supplied to the heater element 170 to maintain the substrate at a desired temperature.

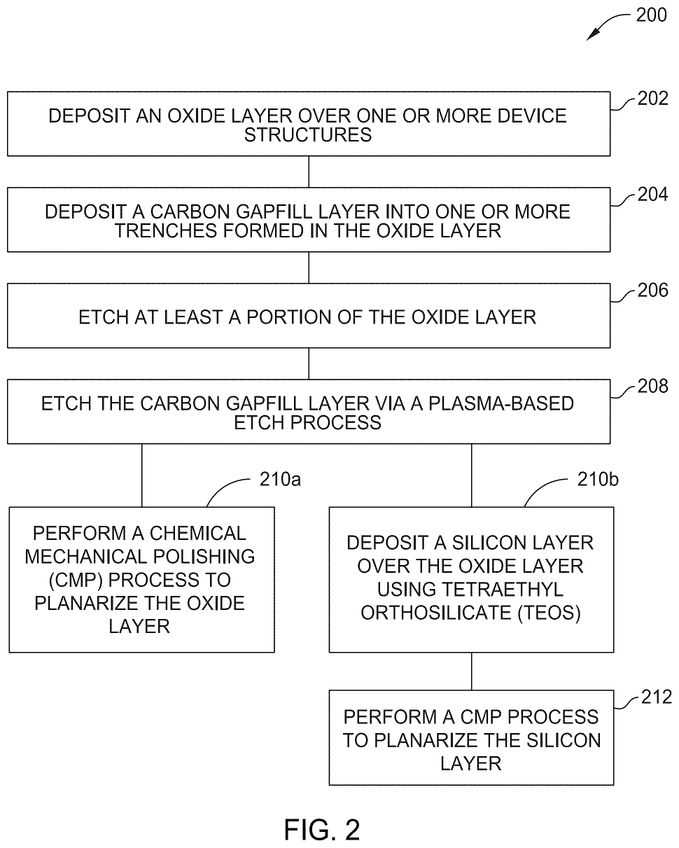

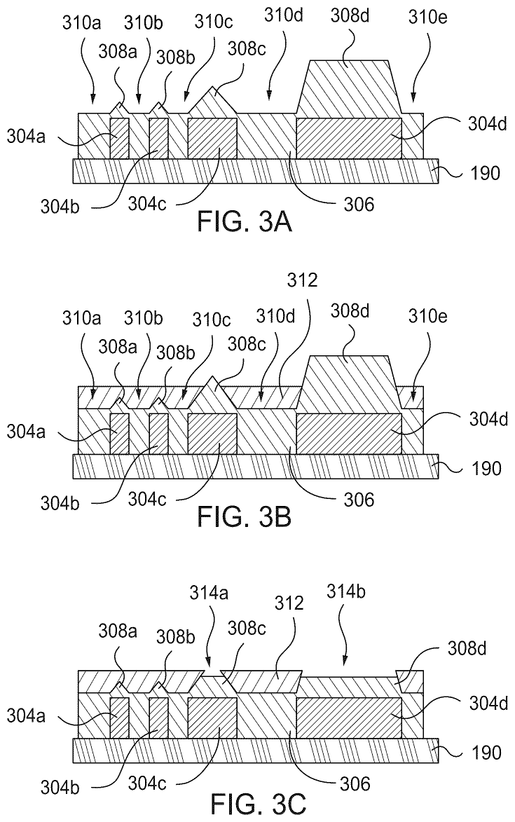

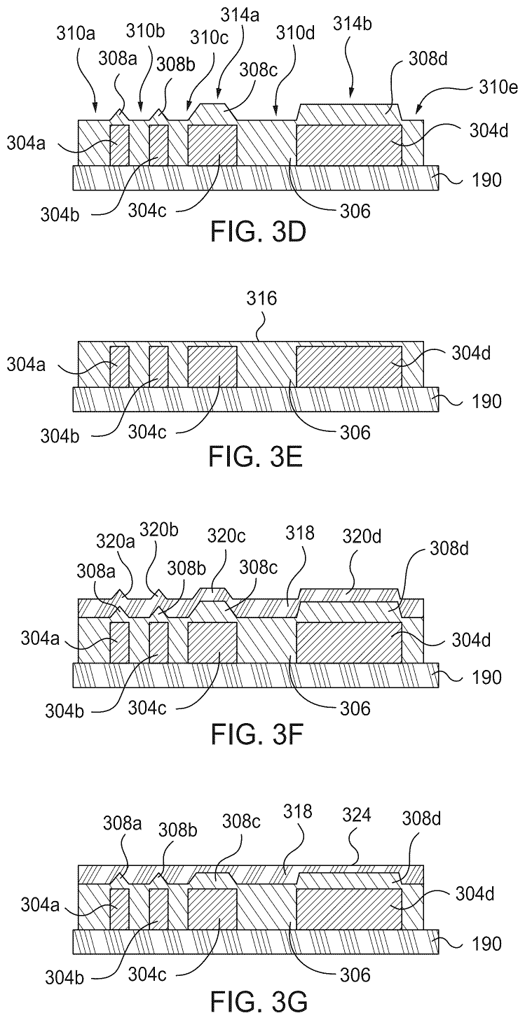

To facilitate transfer of the substrate 190 to and from the substrate support 150, the substrate support 150 includes a plurality of lift pins 152. The plurality of lift pins 152 are movably disposed in openings formed through the substrate support 150. Generally, the lift pins 152 are configured to press against a bottom surface 193 of the substrate 190 to lift the substrate 190 upwards, off the support surface 192 of the substrate support 150 and the first edge ring 180 and toward the top 124. Movement of the lift pins 152 and the substrate 190 is described in further detail with reference to FIG. 2 and FIGS. 3A-3G.

A vacuum pump 102 is coupled to a port formed in the bottom of the processing chamber 100. The vacuum pump 102 can be used to maintain a desired gas pressure in the processing chamber 100. The vacuum pump 102 also evacuates post-processing gases and by-products of the process from the processing chamber 100. Although not shown, the substrate processing system 132 may further include additional equipment for controlling the chamber pressure, for example, valves (e.g., throttle valves and isolation valves) positioned between the processing chamber 100 and the vacuum pump 102 to control the chamber pressure.

A showerhead 120 having a plurality of apertures 128 is disposed on the top of the processing chamber 100 above the substrate support 150. The apertures 128 of the showerhead 120 are utilized to introduce deposition gas into the processing chamber 100. The apertures 128 may have different sizes, number, distributions, shape, design, and diameters to facilitate the flow of the various deposition gases for different process requirements. The showerhead 120 is connected to the gas panel 130 that allows the deposition gas to supply to the interior processing volume 126 during processing. A deposition plasma 135 is formed from the deposition gas exiting the showerhead 120 to enhance thermal decomposition of the deposition gas, resulting in the deposition of material on a top surface 191 of the substrate 190.

One or more radio frequency (RF) power sources 140 provide a bias potential (e.g., RF bias) through a matching network 138 to the showerhead 120 to facilitate generation of the deposition plasma 135. As an example, the RF power sources 140 may provide between 100 watts (W) and 3,000 W at a frequency ranging between 2 megahertz (MHz) and 60 MHz. The RF power sources 140 and matching network 138 may also be coupled to the substrate support 150 and/or an antenna (not shown) disposed exterior to the processing chamber 100. As such, the showerhead 120 and the substrate support 150 may form a pair of spaced apart electrodes in the interior processing volume 126.

The controller 110 includes a central processing unit (CPU) 112, a memory 116, and a support circuit 114 utilized to control the process sequence and regulate the gas flows from the gas panel 130. The CPU 112 can be of any form of a general purpose computer processor that can be used in an industrial setting. The software routines can be stored in the memory 116, such as random access memory, read only memory, floppy, or hard disk drive, or other form of digital storage. The support circuit 114 is conventionally coupled to the CPU 112 and may include cache, clock circuits, input/output systems, power supplies, and the like. Bi-directional communications between the controller 110 and the various components of the substrate processing system 132 are handled through numerous signal cables collectively referred to as signal buses 118, some of which are illustrated in FIG. 1.

Other deposition chambers may also benefit from the deposition processes described and discussed herein and the parameters listed above may vary according to the particular deposition chamber used to process the substrate 190. For example, other deposition chambers may have a larger or smaller volume, requiring gas flow rates that are larger or smaller than those recited for deposition chambers available from Applied Materials, Inc. In one or more embodiments, film can be deposited using a PRODUCER® SE or GT processing chamber or system which is commercially available from Applied Materials, Inc., Santa Clara, California.

Techniques for processing the substrate 190 are described with reference to FIG. 2 and FIGS. 3A-3G, and can be implemented by the controller 110 of FIG. 1. FIG. 2 is a flow diagram of a method 200 of processing the substrate 190 of FIG. 1, according to embodiments. FIGS. 3A-3G show schematic cross-sectional views of the substrate 190 of FIG. 1 at various stages of the method 200 of FIG. 2, according to embodiments. Accordingly, FIG. 2 and FIGS. 3A-3G are described together herein for clarity purposes.

In general, the method 200 is a technique for forming one or more layers on the substrate 190 of FIG. 1. More particularly, the technique of the method 200 provides for efficient manufacturing and improved topography of the substrate 190.

The method 200 begins at operation 202, where an oxide layer 306 is deposited over one or more device structures 304 (first device structure 304a, second device structure 304b, third device structure 304c, and fourth device structure 304d (device structures 304a-d) are shown) formed on the substrate 190, as shown in FIG. 3A. The device structures 304a-d may be formed of one or more materials used for semiconductor devices such as metal contacts, trench isolations, gates, bitlines, or any other interconnect features. The oxide layer 306 is deposited via a HDPCVD process. In at least one embodiment, the HDPCVD process utilizes an inductively coupled plasma (ICP) to generate a high-density plasma for forming an amorphous silicon-containing layer or a microcrystalline silicon-containing layer of the device structures 304a-d and/or substrate 190. However, other types of deposition processes are also contemplated, including other plasma-enhanced CVD (PECVD) processes and the like.

Depositing the oxide layer 306 via HDPCVD can result in one or more overburden structures 308 (first overburden structure 308a, second overburden structure 308b, third overburden structure 308c, and fourth overburden structure 308d (overburden structures 308a-d) are shown) being formed on the device structures 304a-d. The overburden structures 308a-d typically result from excess material being unintentionally deposited onto the device structures 304a-d. Generally, a thickness of each of the overburden structures 308a-d formed during operation 202 depends on lateral dimension(s) of an underlying structure. For example, a thickness of the fourth overburden structure 308d will be greater than a thickness of the first overburden structure 308a after operation 202 because the fourth device structure 304d has greater lateral dimensions (e.g., is wider) than that of the first device structure 304a. As such, the thickness of the overburden structures 308a-d varies across the substrate 190, resulting in a non-uniform substrate topography.

Further, depositing the oxide layer 306 via HDPCVD forms one or more trenches 310 (first trench 310a, second trench 310b, third trench 310c, fourth trench 310d, and fifth trench 310e (trenches 310a-e) are shown) between the overburden structures 308a-d of the oxide layer 306. The trenches 310a-e may also be referred to as open areas, voids, or the like.

While the substrate 190 is illustrated as a single layer, it is understood that the substrate 190 may include one or more layers formed of metal, dielectric material(s), semiconductor material(s), and/or combinations thereof. In certain embodiments, the substrate 190 may include a layer formed of an oxide material, a nitride material, a polysilicon material, or the like, depending upon the application of the overall semiconductor device being fabricated. In certain embodiments, the substrate 190 includes one or more layers formed of crystalline silicon, silicon oxide, silicon oxynitride, silicon nitride, strained silicon, silicon germanium, tungsten, titanium nitride, doped or undoped polysilicon, doped or undoped silicon, silicon on insulator (SOI), carbon doped silicon oxide, silicon nitride, doped silicon, germanium, gallium arsenide, glass, sapphire, low-k dielectrics, and/or combinations thereof. In certain embodiments, the substrate 190 includes a patterned or non-patterned wafer.

At operation 204, a carbon gapfill layer 312 is deposited over/into at least the trenches 310a-e of the oxide layer 306, as shown in FIG. 3B. The carbon gapfill layer 312 protects the trenches 310a-e and the first overburden structure 308a and the second overburden structure 308b during subsequent operations of the method 200.

Generally, the following exemplary process parameters may be used for the carbon gapfill layer 312 formation process described herein. The processing temperature inside the processing chamber 100 may range between 200° C. and 1000° C. (e.g., between 300° C. and 600° C.). The chamber pressure may range from 1 Torr to 10 Torr (e.g., between 2 Torr and 8 Torr, or 5 Torr and 8 Torr). The RF power may be between 500 Watts (W) and 1500 W at any RF (e.g., high frequency radio frequency (HFRF), low frequency RF (LFRF), very high frequency RF (VHRF), etc.). For example, the RF power may be provided at a HFRF of 13.56 MHz, or a LFRF of 300 kilohertz (kHz).

In certain embodiments, depositing the carbon gapfill layer 312 includes introducing a hydrocarbon precursor gas into the processing chamber 100. The hydrocarbon precursor gas can include a hydrocarbon compound having a general formula CₓH_{y}, where x has a range of between 1 and 20 and y has a range of between 1 and 20. Suitable carbon compounds include, for example, methane (CH₄), ethylene (C₂H₄), ethane (C₂H₆), butylenes (C₄H₈), cyclobutane (C₄H₈), and methylcyclopropane (C₄H₈). Suitable butylenes include, for example, 1-Butene, 2-Butene, and isobutylene. The hydrocarbon source can be any liquid or gas. In one embodiment, the hydrocarbon precursor gas includes acetylene (C₂H₂). In another embodiment, the hydrocarbon precursor gas includes propylene (C₃H₆). In one example, the hydrocarbon precursor gas is vapor at room temperature. As an example, the flow rate of the hydrocarbon precursor gas may range from 100 standard cubic centimeter per minute (sccm) to 400 sccm. In some embodiments, the flow rate of the dilution gas may individually range from 0 sccm to 5,000 sccm (e.g., from 2,000 sccm to 4,000 sccm).

In certain embodiments, depositing the carbon gapfill layer 312 further includes generating plasma in the processing chamber 100 to form the carbon gapfill layer 312. The plasma can be formed by capacitive means, and can be energized by coupling RF power into the processing gas mixture.

At operation 206, at least a portion of the oxide layer 306 is etched away, as shown in FIG. 3C. The oxide layer 306 may be etched, for example, via a wet etch process or a dry etch process.

The wet etch process can use a distilled hydrofluoric acid (d-HF) solution. The wet etch process provides a wet clean loading effect that favors planarization of the overall topography. For example, the wider the structure (e.g., fourth overburden structure 308d), the greater the wet etch rate of the oxide layer 306 deposited over the structure.

The dry etch process can use ammonia (NH₃) and/or hydrofluoric acid (HF). As another example, the dry etch process includes a plasma-based dry etch process. The plasma-based dry etch process may include an anisotropic remote plasma assisted dry etch process, such as a reactive ion etching (RIE) process using a plasma formed from a gas including argon (Ar), helium (He), nitrogen (N₂), or a combination thereof. The plasma effluents directionally bombard and remove the portions of the oxide layer 306.

Both the wet and dry etch processes are selective for the oxide layer 306, and thus do not readily etch the carbon gapfill layer 312. When the oxide layer 306 is etched, the carbon gapfill layer 312 is not affected, or is only imperceptibly affected, because an etch selectivity of the oxide layer 306 is greater than an etch selectivity of the carbon gapfill layer 312. In other words, an etch rate of the oxide layer 306 is greater than an etch rate of carbon gapfill layer 312, so the carbon gapfill layer 312 is not etched, or is not substantively etched. Further, because the first overburden structure 308a and the second overburden structure 308b are masked by the carbon gapfill layer 312, only portions of the third overburden structure 308c and the fourth overburden structure 308d are etched.

As a result of the etch process, a first planar surface 314a and a second planar surface 314b (planar surfaces 314a-b) are formed on the third overburden structure 308c and the fourth overburden structure 308d, respectively. Further, a thickness of the overburden structures 308a-d may be substantially equal. Accordingly, the topography of the substrate 190 is greatly improved, or planarized, after the etch process at operation 206.

At operation 208, the carbon gapfill layer 312 is etched away via a plasma-based etch process, as shown in FIG. 3D. The plasma-based etch process removes the carbon gapfill layer 312 from the substrate 190, exposing the trenches 310a-e. The oxide layer 306 is not affected, or is only imperceptibly affected, because plasma does not bind to the oxide layer 306 and does not etch, or does not substantively etch, the overburden structures 308a-d. In other words, an etch selectivity of the carbon gapfill layer 312 is greater than an etch selectivity of the oxide layer 306 (i.e., an etch rate of the carbon gapfill layer 312 is greater than an etch rate of the oxide layer 306).

In certain embodiments, the plasma at operation 208 is formed from oxygen (O₂) and Ar precursors. In certain embodiments, where the precursors at operation 208 include oxygen and argon, oxygen may be delivered with argon at a flow rate ratio of argon to oxygen of greater than 0.5:1, and may be delivered at a flow rate ratio of greater than 1:1 (e.g., greater than 1.5:1, 2:1, 2.5:1, 3.0:1, or more). In certain embodiments, a flow rate of argon is greater than 200 sccm (e.g., greater than 250 sccm, 500 sccm, 750 sccm, or more). In certain embodiments, a flow rate of oxygen is greater than 50 sccm (e.g., greater than 100 sccm, 150 sccm, 200 sccm, or more).

In certain embodiments, operation 208 may be performed at a temperature below 100° C. (e.g., less than 80° C., 60° C., 40° C., or lower). Pressure within the processing chamber 100 may be kept relatively low, such as at a pressure of less than 5 Torr, and pressure may be maintained at less than 1 Torr (e.g., less than 0.75 Torr, 0.5 Torr, 0.25 Torr, or less).

The plasma-based etch process at operation 208 may be performed in the same processing chamber 100 as one or more of operations 202, 204, and/or 206 (i.e., in-situ), or may be performed in a separate processing chamber (i.e., ex-situ).

After the operation 208, the method 200 can proceed to operation 210a or operation 210b. For example, the method 200 proceeds to operation 210a if the deposition of material layers on the substrate 190 is complete. Alternatively, the method 200 proceeds to operation 210b if a silicon layer 318 is to be deposited on the substrate 190.

At operation 210a, a chemical mechanical polishing (CMP) process is performed to planarize the oxide layer 306, as shown in FIG. 3E. In general, the CMP process includes contacting a material layer of a substrate, such as the oxide layer 306 of the substrate 190, to be planarized with a polishing pad and moving the polishing pad, the substrate 190, or both, hence creating relative movement between the oxide layer 306 and the polishing pad, in the presence of a polishing fluid. Portions of the oxide layer 306 (e.g., portions of overburden structures 308a-d) are removed across the oxide layer 306 surface in contact with the polishing pad through a combination of chemical and mechanical activity, which is provided at least in part by the polishing fluid. Commonly used polishing fluids include abrasive particle-containing slurries, e.g., colloids or suspensions, reactive liquid (abrasive-free) slurries, and abrasive-free or reduced-abrasive polishing fluids used in conjunction with fixed-abrasive polishing pads having abrasive particles disposed therein. As a result, the CMP process forms a planar surface 316 on the oxide layer 306 by planarizing the overburden structures 308a-d.

Because the thickness of the third overburden structure 308c and the fourth overburden structure 308d was reduced via the etching of the oxide layer 306 at operation 206, the CMP process at operation 210a is quicker and more efficient, e.g., relative to performing the CMP process on the un-etched third overburden structure 308c and fourth overburden structure 308d. As a result, manufacturing costs associated with the CMP process are reduced because it takes less time to perform operation 210a.

At operation 210b, the silicon layer 318 is deposited over the oxide layer 306 using tetraethyl orthosilicate (TEOS), as shown in FIG. 3F. Depositing the silicon layer 318 over the oxide layer 306 can form one or more material structures 320 (first material structure 320a, second material structure 320b, third material structure 320c, and fourth material structure 320d (material structures 320a-d) are shown) over the overburden structures, 308a, 308b, 308c, and 308d, respectively, which add undesired material to the overburden structures.

Generally, depositing the silicon layer 318 includes providing a silicon containing gas, O₂, and a carrier gas into the processing chamber 100, heating the substrate support 150 to a temperature of 250° C. to 650° C. (e.g., 450° C. to 650° C., 500° C. to 600° C., or 550° C. to 600° C.), and operating the processing chamber 100 between a pressure of 0 Torr to 20 Torr (e.g., 2 Torr to 18 Torr, 5 Torr to 15 Torr, or 8 Torr to 12 Torr), a HFRF power of 0 W to 4,000 W (e.g., 100 W to 4,000 W, 500 W to 4,000 W, or 1,000 W to 4,000 W), and a LFRF power of 0 W to 1,000 W (e.g., 10 W to 1,000 W, 50 W to 1,000 W, or 50 W to 500 W).

In certain embodiments, the silicon containing gas includes TEOS, which is introduced to the processing chamber 100 in an amount of 0 milligrams per cubic meter (mg/m³) to 20,000 mg/m³ (e.g., 100 mg/m3 to 20,000 mg/m³, 500 mg/m³ to 20,000 mg/m³, or 1,000 mg/m³ to 20,000 mg/m³). In certain embodiments, O₂ is flowed into the processing chamber 100 at a flow rate of 0 sccm to 50,000 sccm (e.g., 100 sccm to 50,000 sccm, 500 sccm to 40,000 sccm, or 1,000 sccm to 40,000 sccm). In certain embodiments, the carrier gas may include Ar, He, or combinations thereof, and is flowed into the processing chamber 100 at a flow rate of 0 sccm to 30,000 sccm (e.g., 100 sccm to 30,000 sccm, 500 sccm to 25,000 sccm, or 1,000 sccm to 20,000 sccm).

In certain embodiments, the silicon layer 318 can also be doped with N₂ for form an N doped silicon layer 318. Depositing the N doped silicon layer 318 may additionally include introducing N₂ into the processing chamber 100. The N₂ can be introduced into the processing chamber 100 at a flow rate of 0 sccm to 10,000 sccm (e.g., 100 sccm to 8,000 sccm, or 5,000 sccm to 10,000 sccm).

Typically, the thickness of the third overburden structure 308c and the fourth overburden structure 308d would be reduced via a CMP process before operation 210b. However, because the thickness of the third overburden structure 308c and the fourth overburden structure 308d was reduced via the etching of the oxide layer 306 at operation 206, the silicon layer 318 can be deposited without performing the CMP process prior to operation 210b. As a result, manufacturing costs associated with the CMP process are reduced because the thickness of the third overburden structure 308c and the fourth overburden structure 308d was reduced via etching at operation 210a.

At operation 212, a CMP process is performed to planarize the silicon layer 318, as shown in FIG. 3G. The CMP process performed at operation 212 may be similar to the CMP process described with respect to operation 210a. Thus, the CMP process forms a planar surface 324 on the silicon layer 318 by planarizing the silicon material structures 320a-d.

By depositing the carbon gapfill layer 312 at operation 204 and etching portions of the oxide layer 306 at operation 206, costs related to performing the CMP process to reduce the thickness of the third overburden structure 308c and the fourth overburden structure 308d are reduced. And, the topography of the substrate 190 is improved because the overburden structures 308a-d have a substantially equal thickness. Further, the method 200 improves the overall manufacturing efficiency of the substrate 190 relative to conventional planarization techniques.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

While various examples of the invention have been described above, it should be understood that they have been presented by way of example only, and not by way of limitation. Likewise, the various diagrams may depict an example architectural or other configuration for the disclosure, which is done to aid in understanding the features and functionality that can be included in the disclosure. The disclosure is not restricted to the illustrated example architectures or configurations, but can be implemented using a variety of alternative architectures and configurations. Additionally, although the disclosure is described above in terms of various example examples and aspects, it should be understood that the various features and functionality described in one or more of the individual examples are not limited in their applicability to the particular example with which they are described. They instead can be applied, alone or in some combination, to one or more of the other examples of the disclosure, whether or not such examples are described, and whether or not such features are presented as being a part of a described example. Thus the breadth and scope of the present disclosure should not be limited by any of the above-described example examples.

All references cited herein are incorporated herein by reference in their entirety. To the extent publications and patents or patent applications incorporated by reference contradict the disclosure contained in the specification, the specification is intended to supersede and/or take precedence over any such contradictory material.

Unless otherwise defined, all terms (including technical and scientific terms) are to be given their ordinary and customary meaning to a person of ordinary skill in the art, and are not to be limited to a special or customized meaning unless expressly so defined herein.

Terms and phrases used in this application, and variations thereof, especially in the appended claims, unless otherwise expressly stated, should be construed as open ended as opposed to limiting. As examples of the foregoing, the term ‘including’ should be read to mean ‘including, without limitation,’ ‘including but not limited to,’ or the like; the term ‘including’ as used herein is synonymous with ‘including,’ ‘containing,’ or ‘characterized by,’ and is inclusive or open-ended and does not exclude additional, unrecited elements or method steps; the term ‘having’ should be interpreted as ‘having at least;’ the term ‘includes’ should be interpreted as ‘includes but is not limited to;’ the term ‘example’ is used to provide example instances of the item in discussion, not an exhaustive or limiting list thereof; adjectives such as ‘known’, ‘normal’, ‘standard’, and terms of similar meaning should not be construed as limiting the item described to a given time period or to an item available as of a given time, but instead should be read to encompass known, normal, or standard technologies that may be available or known now or at any time in the future; and use of terms like ‘preferably,’ ‘preferred,’ ‘desired,’ or ‘desirable,’ and words of similar meaning should not be understood as implying that certain features are critical, essential, or even important to the structure or function of the invention, but instead as merely intended to highlight alternative or additional features that may or may not be utilized in a particular example of the invention. Likewise, a group of items linked with the conjunction ‘and’ should not be read as requiring that each and every one of those items be present in the grouping, but rather should be read as ‘and/or’ unless expressly stated otherwise. Similarly, a group of items linked with the conjunction ‘or’ should not be read as requiring mutual exclusivity among that group, but rather should be read as ‘and/or’ unless expressly stated otherwise.

The term “including” as used herein is synonymous with “including,” “containing,” or “characterized by” and is inclusive or open-ended and does not exclude additional, unrecited elements or method steps.

All numbers expressing quantities of ingredients, reaction conditions, and so forth used in the specification are to be understood as being modified in all instances by the term ‘about.’ Accordingly, unless indicated to the contrary, the numerical parameters set forth herein are approximations that may vary depending upon the desired properties sought to be obtained. At the very least, and not as an attempt to limit the application of the doctrine of equivalents to the scope of any claims in any application claiming priority to the present application, each numerical parameter should be construed in light of the number of significant digits and ordinary rounding approaches.

Furthermore, although the foregoing has been described in some detail by way of illustrations and examples for purposes of clarity and understanding, it is apparent to those skilled in the art that certain changes and modifications may be practiced. Therefore, the description and examples should not be construed as limiting the scope of the invention to the specific examples and examples described herein, but rather to also cover all modification and alternatives coming with the true scope and spirit of the invention.

What is claimed is:

1. A processing method, comprising:
depositing a carbon gapfill layer into one or more trenches formed in an oxide layer of a semiconductor device structure;
etching at least a portion of the oxide layer;
etching, via a plasma-based etch process, the carbon gapfill layer; and
performing a chemical mechanical polishing (CMP) process to planarize the oxide layer.

2. The processing method of claim 1, wherein the etching of the at least the portion of the oxide layer comprises an etch selectivity of the oxide layer that is greater than an etch selectivity of the carbon gapfill layer.

3. The processing method of claim 1, wherein the etching of the at least the portion of the oxide layer forms one or more overburden structures having a substantially equal thickness.

4. The processing method of claim 1, wherein the etching of the at least the portion of the oxide layer comprises a wet etch process.

5. The processing method of claim 1, wherein the etching of the at least the portion of the oxide layer comprises dry etch process.

6. The processing method of claim 1, wherein the etching of the carbon gapfill layer comprises an etch selectivity of the oxide layer that is greater than an etch selectivity of the carbon gapfill layer.

7. The processing method of claim 1, wherein the plasma-based etch process is performed in-situ.

8. The processing method of claim 1, wherein the plasma-based etch process is performed ex-situ.

9. A processing method, comprising:
depositing a carbon gapfill layer into one or more trenches formed in an oxide layer of a semiconductor device structure, the oxide layer formed by high-density plasma chemical vapor deposition (HDPCVD);
etching at least a portion of the oxide layer;
etching, via a plasma-based etch process, the carbon gapfill layer;
depositing a silicon layer over the oxide layer using tetraethyl orthosilicate (TEOS); and
performing a chemical mechanical polishing (CMP) process to planarize the silicon layer.

10. The processing method of claim 9, wherein the etching of the at least the portion of the oxide layer comprises an etch selectivity of the oxide layer that is greater than an etch selectivity of the carbon gapfill layer.

11. The processing method of claim 9, wherein the etching of the at least the portion of the oxide layer forms one or more overburden structures having a substantially equal thickness.

12. The processing method of claim 9, wherein the etching of the at least the portion of the oxide layer comprises a wet etch process.

13. The processing method of claim 9, wherein the etching of the at least the portion of the oxide layer comprises dry etch process.

14. The processing method of claim 12, wherein the etching of the carbon gapfill layer comprises an etch selectivity of the oxide layer that is greater than an etch selectivity of the carbon gapfill layer.

15. The processing method of claim 12, wherein the plasma-based etch process is performed in-situ.

16. The processing method of claim 12, wherein the plasma-based etch process is performed ex-situ.

17. A processing method, comprising:
depositing, via a high-density plasma (HDP) deposition process, an oxide layer over one or more device structures;
depositing a carbon gapfill layer into one or more trenches formed in the oxide layer;
etching at least a portion of the oxide layer;
etching, via a plasma-based etch process, the carbon gapfill layer;
depositing a silicon layer over the oxide layer using tetraethyl orthosilicate (TEOS); and
performing a chemical mechanical polishing (CMP) process to planarize the silicon layer.

18. The processing method of claim 17, wherein the etching of the at least the portion of the oxide layer comprises an etch selectivity of the oxide layer that is greater than an etch selectivity of the carbon gapfill layer.

19. The processing method of claim 17, wherein the etching of the at least the portion of the oxide layer forms one or more overburden structures having a substantially equal thickness.

20. The processing method of claim 17, wherein the etching of the carbon gapfill layer comprises an etch selectivity of the oxide layer that is greater than an etch selectivity of the carbon gapfill layer.
